(19) United States
(12) Patent Application Publication
(10) Pub. No.: US 2026/0107655 A1
(43) Pub. Date: Apr. 16, 2026

(54) DISPLAY DEVICE AND ELECTRONIC DEVICE INCLUDING THE SAME

(71) Applicant: Samsung Display Co., Ltd., Yongin-Si (KR)

(72) Inventor: Hyeon Bum LEE, Yongin-si (KR)

(21) Appl. No.: 19/278,776

(22) Filed: Jul. 24, 2025

(30) Foreign Application Priority Data
Oct. 15, 2024 (KR) 10-2024-0140488

(51) Int. Cl. H10K 59/38; H10K 59/40; H10K 59/80

(52) U.S. Cl. CPC H10K 59/38; H10K 59/40; H10K 59/8792

(57) ABSTRACT

A display device includes a light-emitting region including first, second, and third light-emitting devices that are spaced apart from each other, and a color filter layer including a light-shielding portion, a first color filter that overlaps the first light-emitting device in a thickness direction, a second color filter that overlaps the second light-emitting device in the thickness direction, and a third color filter that overlaps the third light-emitting device in the thickness direction. One end portion of the first color filter is disposed on the light-shielding portion, and one end portion of the third color filter is disposed on the first color filter arranged on the light-shielding portion. A first spacing distance between the one end portion of the first color filter and the one end portion of the third color filter in a plan view is in a range from 0.1 μm to 5.0 μm.

### CROSS-REFERENCE TO RELATED APPLICATION AND CLAIM OF PRIORITY

This application claims priority to Korean Patent Application No. 10-2024-0140488 filed on Oct. 15, 2024 in the Korean Intellectual Property Office (KIPO), the entire disclosure of which is incorporated by reference herein.

### TECHNICAL FIELD

The disclosure of this patent application relates to a display device and electronic device including the same. More particularly, the disclosure of this patent application relates to a display device including an emission layer and a color-control layer, and an electronic device including the same.

### BACKGROUND

An organic light-emitting device has a self-luminous property, and may provide improved viewing angle and contrast properties. Additionally, a high response speed and a high luminance may be provided. The display device has a plurality of pixels. The plurality of pixels may emit lights of different colors, and the pixels may include a color filter to improve a color purity.

For example, a color generated by a light-emitting portion of the pixel may be emitted to an outside through the color filter without an additional polarizing layer.

### SUMMARY

According to an aspect of the present disclosure, there is provided a display device having improved light-emitting efficiency, color purity and luminance.

According to an aspect of the present disclosure, there is provided an electronic device having improved light-emitting efficiency, color purity and luminance.

A display device may include a light-emitting region including a first light-emitting device, a second light-emitting device and a third light-emitting device that are spaced apart from each other, and a color filter layer including a light-shielding portion, a first color filter that overlaps the first light-emitting device in a thickness direction, a second color filter that overlaps the second light-emitting device in the thickness direction, and a third color filter that overlaps the third light-emitting device in the thickness direction. One end portion of the first color filter may be disposed on the light-shielding portion, and one end portion of the third color filter may be disposed on the first color filter on the light-shielding portion. A first spacing distance between the one end portion of the first color filter and the one end portion of the third color filter in a plan view may be in a range from 0.1 μm to 5.0 μm.

In some embodiments, the first spacing distance may be in a range from 0.5 m to 3.5 μm.

In some embodiments, the light-shielding portion may be disposed between the first light-emitting device and the second light-emitting device, between the second light-emitting device and the third light-emitting device, and between the first light-emitting device and the third light-emitting device in the plan view.

In some embodiments, the one end portion of the first color filter and the one end portion of the third color filter may be sequentially arranged on the light-shielding portion adjacent to the second color filter.

In some embodiments, the second color filter may cover the one end portion of the third color filter in the thickness direction.

In some embodiments, the light-emitting region may further include a pixel defining layer that includes a first opening exposing the first light-emitting device, the second light-emitting device or the third light-emitting device.

In some embodiments, the first opening may have a circular shape or an elliptical shape.

In some embodiments, the first opening may be defined by a side wall of the pixel defining layer.

In some embodiments, the color filter layer may include a second opening that exposes the first color filter, the second color filter or the third color filter.

In some embodiments, the second opening may have a circular shape or an elliptical shape.

In some embodiments, the second opening may be defined by a side wall of the light-shielding portion.

In some embodiments, the light-emitting region may further include a pixel defining layer including a first opening that exposes the first light-emitting device, the second light-emitting device or the third light-emitting device. The color filter layer may include a second opening exposing the first color filter, the second color filter or the third color filter. A diameter of the second opening may be larger than a diameter of the first opening in the plan view.

In some embodiments, a second spacing distance between one end portion of the light-shielding portion and the one end portion of the first color filter in the plan view may be in a range from 0.1 μm to 5.0 μm.

In some embodiments, the second spacing distance may be in a range from 0.5 μm to 3.5 μm.

In some embodiments, the first light-emitting device, the second light-emitting device and the third light-emitting device may be a red light-emitting device, a green light-emitting device and a blue light-emitting device, respectively. The first color filter, the second color filter and the third color filter may be a red color filter, a green color filter and a blue color filter, respectively.

A display device may include a substrate, a first light-emitting device, a second light-emitting device and a third light-emitting device spaced apart from each other on the substrate, an encapsulation layer covering the first light-emitting device, the second light-emitting device and the third light-emitting device on the substrate, a touch sensor layer disposed on the encapsulation layer and including a touch sensing electrode pattern, and a color filter layer on the touch sensor layer. The color filter layer may include a first color filter that overlaps the first light-emitting device in a thickness direction, a second color filter that overlaps the second light-emitting device in the thickness direction, and a third color filter that overlaps the third light-emitting device in the thickness direction. One end portion of the first color filter may be disposed on the touch sensing electrode pattern, one end portion of the third color filter may be disposed on the first color filter on the touch sensing electrode pattern. A first spacing distance between the one end portion of the first color filter and the one end portion of the third color filter in a plan view may be in a range from 0.1 μm to 5.0 μm.

In some embodiments, the display device may further include a light-shielding portion covering the touch sensing electrode pattern.

In some embodiments, the touch sensor layer may include a second sensor electrode layer, a sensor insulating interlayer, and a first sensor electrode layer sequentially staked on the encapsulation layer.

In some embodiments, a second spacing distance between one end portion of the touch sensing electrode pattern and the one end portion of the first color filter in the plan view may be in a 0.1 μm to 5.0 μm.

An electronic device may include the above-described display device, a memory, and a processor for executing data included in the memory to control an operation of the display device.

In a display device according to embodiments of the inventive concept, a second opening of a pixel and/or a color filter layer may have a circular shape or an elliptical shape in a plan view. Accordingly, diffraction due to an external light may be suppressed, so that reflectance may be reduced, and color reproducibility may be improved.

One end portion of a first color filter may be disposed on a light-shielding portion, and one end portion of a third color filter may be disposed on the first color filter that may be disposed on the light-shielding portion. Accordingly, reflectance in a boundary region between the pixels may be reduced, and diffraction due to the external light may be reduced.

In a plan view, a first spacing distance between the one end portion of the first color filter and the one end portion of the third color filter may be in a range from 0.1 m to 5.0 μm. In the above range, a reflectance (SCI, SCE) may be decreased while maintaining or improving a side viewing angle luminance ratio (LvA) of the display device and/or the color filter layer.

### BRIEF DESCRIPTION OF THE DRAWINGS

FIG. 1 is a schematic exploded perspective view illustrating a display device in accordance with example embodiments.

FIG. 2 is a schematic cross-sectional view of a display panel in accordance with example embodiments.

FIG. 3 is a schematic plan view illustrating a display device in accordance with example embodiments.

FIG. 4 is a schematic plan view illustrating a pixel arrangement of a display device in accordance with example embodiments.

FIG. 5 is a schematic cross-sectional view of a display panel or a display device in accordance with example embodiments.

FIG. 6 is a partially enlarged cross-sectional view of a region designated as A of FIG. 5.

FIGS. 7A and 7B are schematic cross-sectional views illustrating light-emitting devices in accordance with example embodiments.

FIG. 8 is a schematic cross-sectional view of a display panel or a display device in accordance with some embodiments.

FIG. 9 is a block diagram of an electronic device in accordance with an embodiment.

FIG. 10 is a schematic diagram of an electronic device in accordance with various embodiments.

FIG. 11 is a cross-sectional view of a display device of Comparative Example taken along a line I-I′ of FIG. 4 in a thickness direction.

### DETAILED DESCRIPTION OF THE EMBODIMENTS

Hereinafter, embodiments of the inventive concept will be described in more detail with reference to the attached drawings. The same reference numerals can be used for indicating the same elements in the drawings, and repeated descriptions of the same elements can be omitted. Embodiments disclosed in the attached drawings are exemplary, and is to be understood to include all modifications, equivalents and substitutes included in the spirit and technical scope of the inventive concept.

The terms “on”, “connected”, “coupled,” etc., used herein refers to a direct placement/connection/combination, and also refers to a case where another element is interposed two different elements.

The terms such as “first”, “second”, “below”, “below”, “above,” “above,” etc., are used in a relative sense to distinguish different elements or positions, and do not specify an absolute position or an absolute order.

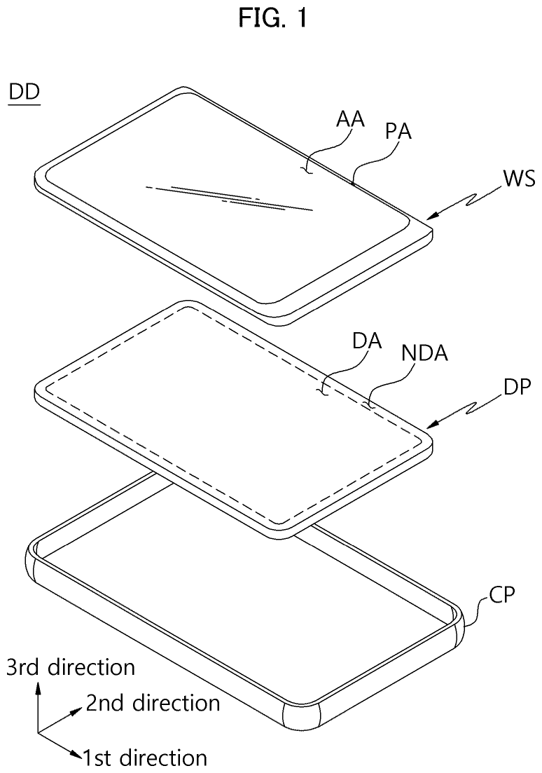

FIG. 1 is a schematic exploded perspective view illustrating a display device DD in accordance with example embodiments.

Referring to FIG. 1, the display device DD may include a window structure WS, a display panel DP and a cover panel CP. The display device DD may include a liquid crystal display (LCD) device, an organic light emitting diode (OLED) display, a quantum dot light emitting diode (QLED) display, etc.

In FIG. 1, a first direction and a second direction may refer to two directions parallel to a display surface of the window structure WS and/or the display panel DP. For example, the first direction and the second direction may be orthogonal to each other. For example, the first direction may correspond to an X-direction (a row direction) of the display device DD or the display panel DP, and the second direction may correspond to a Y-direction (a column direction) of the display device DD or the display panel DP.

A third direction may be perpendicular to the first direction and the second direction. The third direction may correspond to a Z-direction (a thickness direction) of the display device DD or the display panel DP.

In the accompanying drawings, the definition of the direction described above may be equally applied.

The cover panel CP, the display panel DP and the window structure WS may be sequentially stacked in the third direction.

The window structure WS may provide an external display surface recognized by a user of the display device DD, and may include a transparent film. For example, the window structure WS may include glass (e.g., ultra-thin glass UTG), a hard coating film, a plastic film, etc.

An outer surface of the window structure WS may include an active area AA and a peripheral area PA. The active area AA may provide a surface from which an image of the display device DD is substantially displayed and to which a user's touch/command is input. The peripheral area PA may substantially correspond to a bezel area of the display device DD.

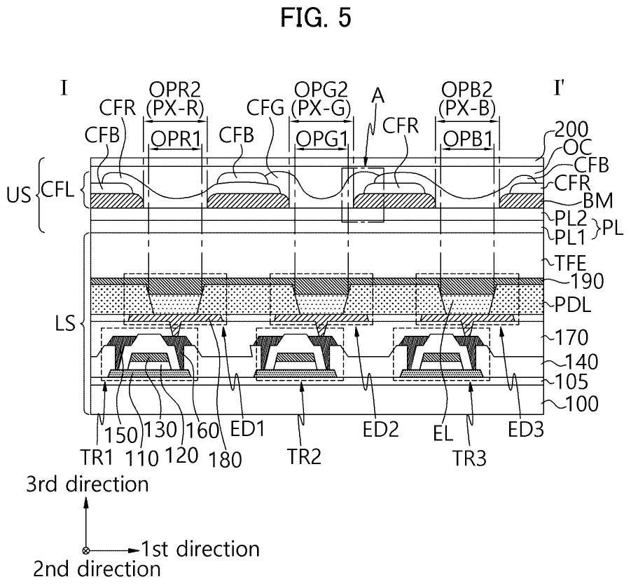

In some embodiments, an upper substrate 200 (e.g., see FIG. 5) may serve as a window structure WS.

The display panel DP may include a display area DA and a non-display area NDA. The display area DA of the display panel DP may substantially correspond to or overlap the active area AA of the window structure WS. The non-display area NDA of the display panel DP may substantially correspond to or overlap the peripheral area PA of the window structure WS.

The cover panel CP may serve as a rear panel or a rear housing of the display device DD. The cover panel CP may include a plate (e.g., a SUS plate) that supports the display panel DP, a circuit board (PCB), etc. The cover panel CP may include an elastic body for absorbing a shock to the display device DD or the electronic device.

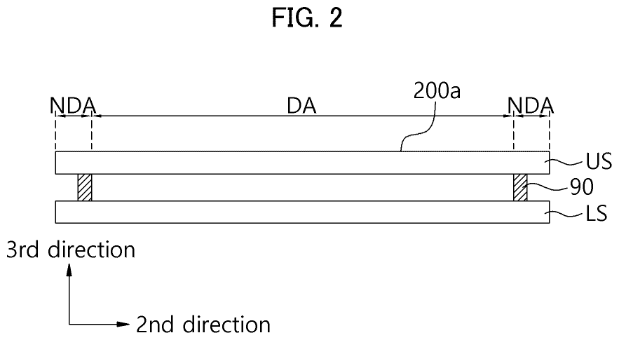

FIG. 2 is a schematic cross-sectional view of a display panel DP according to embodiments.

Referring to FIG. 2, the display panel DP or the display device DD may include an upper structure US and a lower structure LS. As will be described later with reference to FIG. 5, the upper structure US may include an upper substrate 200 and a color filter layer disposed under the upper substrate 200. The lower structure LS may include a lower substrate 100 and a light-emitting device disposed on the lower substrate 100.

In some embodiments, the upper structure US and the lower structure LS may be coupled or laminated to each other by a sealant 90. An active surface or a display surface of the display device DD or the display panel DP may be provided by an outer surface 200a of the upper substrate 200 (e.g., a top surface of the upper substrate 200).

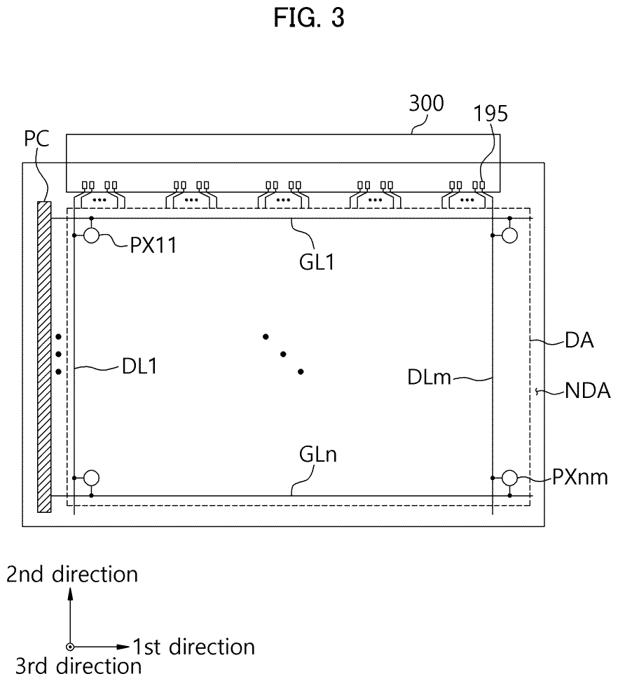

FIG. 3 is a schematic plan view illustrating a display device in accordance with example embodiments.

Referring to FIG. 3, a plurality of pixels PX11 to PXnm may be arranged in the display area DA of the display panel DP.

In example embodiments, a pixel circuit including gate lines GL1 to GLn forming first to n^{th} rows and data lines DL1 to DLm forming first to m^{th} columns may be included in the lower structure LS of the display panel DP. Each of the pixels PX11 to PXnm may be connected to a corresponding n^{th} row gate line among a plurality of gate lines GL1 to GLn and a corresponding m^{th} column data line among a plurality of data lines DL1 to DLm.

Each of the pixels PX11 to PXnm may further include a pixel driving/switching device including a transistor and a light-emitting device as will be described below. Although not illustrated in detail in FIG. 3, the pixel circuit may further include wirings such as a power line, a ground line, etc.

FIG. 3 illustrates that the data lines DL1 to DLm extend in the second direction and the gate lines GL1 to GLn extend in the first direction, but the construction of the data lines and the gate lines is not limited to that illustrated in FIG. 3.

A peripheral circuit PC may be disposed in the peripheral area PA of the display device DD or the non-display area NDA of the display panel DP. For example, the peripheral circuit PC may include a gate driving circuit. The gate driving circuit may be integrated into the display panel DP by an oxide silicon gate driver circuit (OSG) or an amorphous silicon gate driver circuit (ASG) process.

The display device DD may further include a printed circuit board 300. Pads 195 of the pixel circuit may be assembled at one end portion of the non-display area NDA. The printed circuit board 300 may be electrically connected to the pixel circuit through the pads 195. For example, the printed circuit board 300 may be electrically connected to the pads 195 by a heating-compression process using a conductive intermediate structure such as an anisotropic conductive film (ACF).

An integrated circuit (IC) such as a data driving circuit may be disposed on the printed circuit board 300. In some embodiments, an integrated circuit (IC) chip in the form of a chip-on-film (COF) may be mounted on the printed circuit board 300.

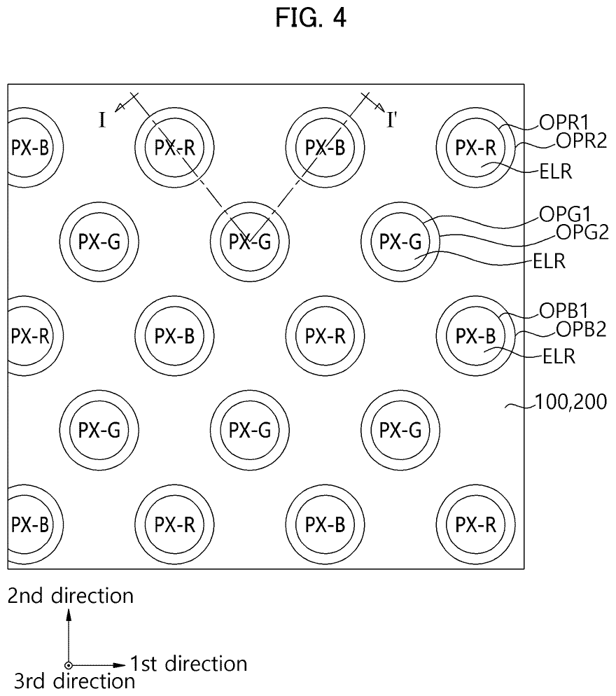

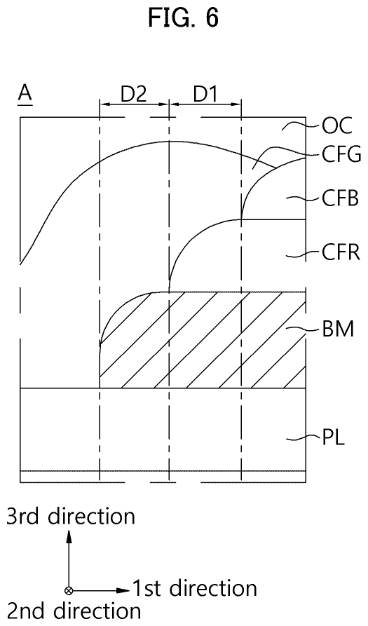

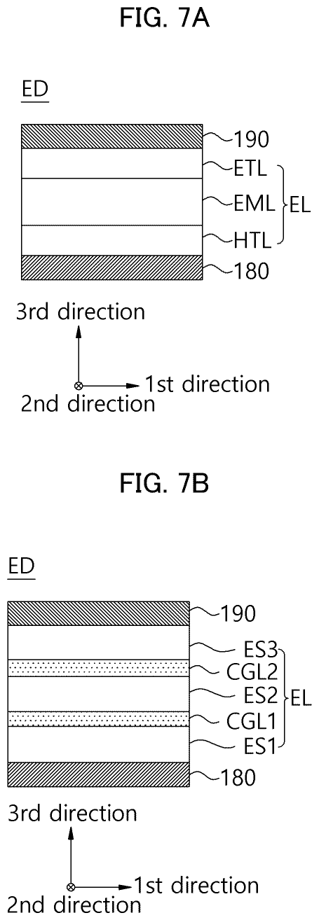

FIG. 4 is a schematic plan view illustrating a pixel arrangement of a display device in accordance with example embodiments. FIG. 5 is a schematic cross-sectional view of a display panel or a display device in accordance with example embodiments. For example, FIG. 5 is a cross-sectional view taken along a line I-I′ of FIG. 4 in a thickness direction (the third direction). FIG. 6 is a partially enlarged cross-sectional view of a region designated as A of FIG. 5. FIGS. 7A and 7B are schematic cross-sectional views illustrating light-emitting devices in accordance with example embodiments.

Referring to FIGS. 4 to 6, pixels of the display device DD may include a first pixel PX-R, a second pixel PX-G and a third pixel PX-B. The first to third pixels PX-R, PX-G and PX-B may correspond to different colors.

In example embodiments, the first pixel PX-R may be a region emitting a red light. For example, the first pixel PX-R may be a region emitting a red light having a central wavelength in a range from 600 nm to 670 nm. The second pixel PX-G may be a region emitting a green light. For example, the second pixel PX-G may be a region emitting a green light having a central wavelength in a range from 500 nm to 580 nm. The third pixel PX-B may be a region emitting a blue light. For example, the third pixel PX-B may be a region emitting a blue light having a central wavelength in a range from 420 nm to 480 nm.

As illustrated in FIG. 4, the first pixel PX-R and the third pixel PX-B may be alternately and repeatedly arranged in the same row (the first direction). The second pixel PX-G may be repeatedly arranged in a different row from that of the first pixel PX-R and the third pixel PX-G.

For example, the first pixel PX-R and the third pixel PX-B may be disposed in the same column (the second direction). The first pixel PX-R and the second pixel PX-G may not be disposed in the same column. The third pixel PX-B and the second pixel PX-G may not be disposed in the same column.

In example embodiments, each of the first pixel PX-R, the second pixel PX-G and the third pixel PX-B may have a circular shape or an elliptical shape. Accordingly, a diffraction due to external light may be suppressed, so that reflectance may be reduced and color reproducibility may be improved.

As described above, the upper structure US and the lower structure LS may be combined to form the display panel DP. According to an embodiment illustrated in FIG. 5, the lower structure LS may include transistors TR1, TR2 and TR3, and a light-emitting portion EL. The upper structure US may include a color filter layer CFL.

The lower structure LS may include the lower substrate 100, the transistors TR1, TR2 and TR3 arranged on the lower substrate 100, and a light-emitting device connected to each of the transistors TR1, TR2 and TR3.

The lower substrate 100 may serve as a base substrate of the display device DD or the display panel DP, or a back-plane substrate. The lower substrate 100 may include a glass substrate, a ceramic substrate, or a plastic substrate. In some embodiments, the lower substrate 100 may include a polymer material having transparency and flexibility. In this case, the lower substrate 100 may be employed in a transparent flexible, or a bendable or foldable display device.

For example, the lower substrate 100 may include a polymer material such as polyimide, polysiloxane, an epoxy resin, an acrylic resin, polyester, polyarylate, polycarbonate, polyethersulfone, polyphenylene sulfide, etc. In an embodiment, the lower substrate 100 may include polyimide.

A buffer layer 105 may be formed on a top surface of the lower substrate 100. Moisture penetrating through the lower substrate 100 may be blocked by the buffer layer 105, and diffusion of impurities between the lower substrate 100 and a structure formed on the lower substrate 100 may be blocked. The buffer layer 105 may be formed entirely over a pixel area (areas designated as PX-G, PX-B and PX-R in FIG. 5) and a non-pixel area substantially overlapping a pixel defining layer PDL of the lower substrate 100, and may entirely cover the top surface of the lower substrate 100.

The buffer layer 105 may include, e.g., an inorganic insulating material such as silicon oxide, silicon nitride, silicon oxynitride, etc. These may be used alone or in a combination of two or more therefrom. In some embodiments, the buffer layer 105 may have a stacked structure including a silicon oxide layer and a silicon nitride layer.

The buffer layer 105 may be formed by a deposition process such as a chemical vapor deposition (CVD) process, a sputtering process, and an atomic layer deposition (ALD) process to include the inorganic insulating material.

The transistors TR1, TR2 and TR3 may be disposed on the buffer layer 105. The first transistor TR1, the second transistor TR2 and the third transistor TR3 may be electrically connected to a first light-emitting device ED1, a second light-emitting device ED2 and a third light-emitting device ED3, respectively.

Each of the transistors TR1, TR2 and TR3 may include an active layer 110, a gate insulation layer 120, a gate electrode 130, and connection electrodes 150 and 160. The transistors TR1, TR2 and TR3 may be electrically connected to the light-emitting device of the first pixel PX-G, the second pixel PX-B and the third pixel PX-R, respectively.

The active layer 110 may be disposed on the buffer layer 105, and may be patterned by, e.g., a photo-lithography process to be repeatedly/regularly arranged at each pixel. The active layer 110 may include a silicon compound such as polysilicon, an amorphous silicon. A p-type dopant or an n-type dopant may be doped in a partial region of the active layer 110, and may include a source region, a drain region and a channel region.

The active layer 110 may include an oxide semiconductor such as indium gallium zinc oxide (IGZO), zinc tin oxide (ZTO) or ITZO.

The gate insulation layer 120 may be formed on the active layer 110, and the gate electrode 130 may be stacked on the gate insulation layer 120. As illustrated in FIG. 5, the gate insulation layer 120 may be formed in a pattern shape partially covering each active layer 110.

In an embodiment, the gate insulation layer 120 may extend continuously over a plurality of the pixel or light-emitting regions, and may be commonly included in the first to third transistors TR1, TR2 and TR3.

The gate electrode 130 may overlap the channel region of the active layer 110 in the third direction.

The gate insulation layer 120 may be formed by the above-described deposition process to include an inorganic insulating material such as silicon oxide, silicon nitride, silicon oxynitride, etc. In some embodiments, the gate insulation layer 120 having a patterned shape may be formed as illustrated in FIG. 5 by a photo-lithography process using the gate electrode 130 substantially as an etching mask.

In some embodiments, the gate electrode 130 and the gate insulation layer 120 may be used as an ion implantation mask to form the source region and the drain region in the active layer 110.

An insulating interlayer 140 covering the gate insulation layer 120 and the gate electrode 130 may be formed on the active layer 110. The connection electrodes 150 and 160 which may be in contact with or electrically connected to the active layer 110 may be formed on the insulating interlayer 140.

The insulating interlayer 140 may be formed by the above-described deposition process to include an inorganic insulating material such as silicon oxide, silicon nitride, and silicon oxynitride. The insulating interlayer 140 may be formed in a single-layered structure or a multi-layered structure including different materials.

In some embodiments, if the active layer 110 includes an oxide semiconductor, hydrogen (H) contained in the insulating interlayer 140 may be diffused or moved to the active layer 110 by a heat treatment process when forming the insulating interlayer 140. Accordingly, a carrier concentration may be increased by hydrogen, and thus the source region and the drain region having increased conductivity may be formed at one lateral portion and the other lateral portion of the active layer 110, respectively.

The connection electrodes 150 and 160 may penetrate the insulating interlayer 140 and may be connected to the active layer 110. When the gate insulation layer 120 is continuously formed commonly in a plurality of the light-emitting regions, the connection electrodes 150 and 160 may also penetrate the gate insulation layer 120.

The connection electrodes 150 and 160 may include a source electrode 150 connected to or in contact with the source region of the active layer 110 and a drain electrode 160 connected to or in contact with the drain region of the active layer 110.

Contact holes may be formed by partially etching the insulating interlayer 140. For example, the contact hole exposing each of the source region and the drain region may be formed. A metal layer sufficiently filling the contact holes may be formed on the insulating interlayer 140, and the metal layer may be partially etched to form the source electrode 150 and the drain electrode 160.

The gate electrode 130 and the connection electrodes 150 and 160 may include a metal such as Ag, Mg, Al, W, Cu, Ni, Cr, Mo, Ti, Pt, Ta, Nd, Sc, an alloy thereof, or a nitride thereof. The gate electrode 130 and the connection electrodes 150 and 160 may be formed by the above-described deposition process.

A planarization layer 170 covering the connection electrodes 150 and 160 may be formed on the insulating interlayer 140. The planarization layer 170 may accommodate a via structure electrically connecting a pixel electrode 180 and the drain electrode 160.

In some embodiments, the planarization layer 170 may include an organic material such as polyimide, an epoxy resin, an acrylic resin, polyester, a siloxane resin, a benzocyclobutene (BCB), or the like. The planarization layer 170 may be formed by the above-described deposition process or a spin coating process.

The pixel electrode 180 may be formed in each pixel to be electrically connected to the transistors TR1, TR2 and TR3. The pixel electrode 180 may be formed on the planarization layer 170 to be electrically connected to the drain electrode 160.

For example, the planarization layer 170 may be partially etched to form a via hole exposing a top surface of the drain electrode 160. A conductive layer including a metal or a transparent conductive oxide and sufficiently filling the via hole may be formed on a top surface of the planarization layer 170, and then the conductive layer may be partially etched to form the pixel electrode 180.

The pixel electrode 180 may serve as an anode, and may include a high work function conductive material to promote a hole injection. The pixel electrode 180 may serve as a transmissive electrode. The pixel electrode 180 may include a transparent conductive oxide such as indium tin oxide (ITO), indium zinc oxide (IZO), zinc oxide (ZnO) and indium tin oxide (ITZO).

The pixel electrode 180 may serve as a translucent electrode or a reflective electrode. The pixel electrode 180 may include a metal selected from Ag, Mg, Cu, Al, Pt, Pd, Au, Ni, Nd, Ir, Cr, Li, Ca, LiF, Mo, Ti, W, In, Sn and Zn, or an alloy of two or more therefrom.

The pixel electrode 180 may have a single-layered structure or a multi-layered structure. For example, the pixel electrode 180 may have a triple-layered structure of ITO/Ag/ITO.

The pixel defining layer PDL exposing a top surface of the pixel electrode 180 may be formed on the planarization layer 170. A light-emitting region may be defined by a sidewall of the pixel defining layer PDL. A light-emitting region ELR (see FIG. 4) including the first light-emitting device ED1, the second light-emitting device ED2, and the third light-emitting device ED3 may be defined by a sidewall of the pixel defining layer PDL. A red light-emitting region, a green light-emitting region and a blue light-emitting region may be separated and defined by the pixel defining layer PDL, and the light-emitting devices ED1, ED2 and ED3 may correspond to a red light-emitting device, a green light-emitting device and a blue light-emitting device, respectively.

As illustrated in FIG. 5, when the sidewall of the pixel defining layer PDL has an inclined shape, the-light emitting region ELR may be defined by an edge where the top surface and the sidewall of the pixel defining layer PDL meet each other.

A photosensitive organic material such as a polysiloxane resin, a polyimide resin or an acrylic resin may be coated, and exposure and development processes may be performed to form the pixel defining layer PDL. In some embodiments, the pixel defining layer PDL may be formed by a printing process such as an inkjet printing process using a polymer material or an inorganic material.

The light-emitting portion EL may be disposed in each light-emitting region ELR formed by the pixel defining layer PDL. In example embodiments, the light-emitting portion EL may include an emission layer including an organic light-emitting material. For example, the light-emitting portion EL may be formed by a process such as a vacuum deposition, a spin coating, an inkjet printing, a laser printing, a casting, a laser thermal transfer, or the like.

In some embodiments, the pixel defining layer PDL may be provided as a black pixel defining layer (BPDL). Accordingly, colors emitted from the light-emitting devices ED1, ED2 and ED3 may be extracted to an outside via the color filter layer CFL without a polarization layer (e.g., an On-Cell Film structure).

In some embodiments, the pixel defining layer PDL may include first openings OPR1, OPG1 and OPB1 exposing the first light-emitting device ED1, the second light-emitting device ED2, and the third light-emitting device ED3. For example, the first openings OPR1, OPG1 and OPB1 may be defined by the sidewalls of the pixel defining layer PDL.

For example, the first light-emitting device ED1 may be exposed through a first-first opening OPR1, the second light-emitting device ED2 may be exposed through a first-second opening OPG1, and the third light-emitting device ED3 may be exposed through a first-third opening OPB1. The “exposure” may indicate an exposure of a top surface. For example, colors emitted from the light-emitting devices ED1, ED2 and ED3 may be exposed to an outside through the first openings OPR1, OPG1 and OPB1 via the color filter layer CFL.

In some embodiments, the first openings OPR1, OPG1 and OPB1 may have a circular shape or an elliptical shape. Accordingly, diffraction and/or reflection due to the external light may be further suppressed.

A counter electrode 190 may be disposed on top surfaces of the pixel defining layer PDL and the light emitting-portion EL. The counter electrode 190 may be a common electrode that is continuously provided commonly in a plurality of the light emitting-regions or the pixels.

The counter electrode 190 may serve as an electron injection electrode or a cathode. The counter electrode 190 may include a metal, an alloy, an electrically conductive compound, or the like, having a low work function.

For example, the counter electrode 190 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or the like. These may be used alone or in combination of two or more therefrom.

The counter electrode 190 may be provided as a transmissive electrode, a translucent electrode, or a reflective electrode. The counter electrode 190 may have a single-layered structure or a multi-layered structure.

The light-emitting device ED1, ED2 and ED3 may be defined by the pixel electrode 180, the light-emitting portion EL and the counter electrode 190. The light-emitting device ED1, ED2 and ED3 may be provided as an organic light-emitting diode (OLED) device. Constructions and structures of the light-emitting portion EL and the light-emitting devices ED1, ED2 and ED3 will be described in more detail with reference to FIGS. 7A and 7B.

An encapsulation layer TFE may be formed on the counter electrode 190. The encapsulation layer TFE may be disposed on the pixel defining layer PDL and the light-emitting devices ED1, ED2 and ED3 to protect the light-emitting devices ED1, ED2 and ED3 from moisture or oxygen.

The encapsulation layer TFE may include an inorganic layer including silicon nitride (SiNx), silicon oxide (SiOx), indium tin oxide, indium zinc oxide, or any combination thereof; an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., aliphatic glycidyl ether (AGE) or any combination thereof; or a combination of the inorganic and organic layers.

The encapsulation layer TFE may be formed in a single-layered or a multi-layered structure. In some embodiments, the encapsulation layer TFE may have a sequential stacked structure of a first inorganic layer, an organic layer and a second inorganic layer.

The color filter layer CFL may be disposed under a bottom surface (a surface facing the lower substrate 100) of the upper substrate 200.

In example embodiments, the color filter layer CFL may include a light-shielding portion BM, a first color filter CFR, a second color filter CFG, and a third color filter CFB.

For example, the color filters CFR, CFG and CFB may selectively transmit a light of a specific wavelength band, and may substantially absorb a remaining light. Accordingly, color purity of the display device DD may be enhanced, and reflection of the external light may be reduced.

The first color filter CFR may overlap the first light-emitting device ED1 in the thickness direction (the third direction), the second color filter CFG may overlap the second light-emitting device ED2 in the thickness direction, and the third color filter CFB may overlap the third light-emitting device ED3 in the thickness direction.

For example, the first color filter CFR, the second color filter CRG and the third color filter CFB may serve as a red color filter, a green color filter, and a blue color filter, respectively.

The first color filter CFR may transmit a red light having a central wavelength in, e.g., a range of 600 nm to 670 nm. The second color filter CFG may transmit a green light having a central wavelength in, e.g., a range of 500 nm to 580 nm. The third color filter CFB may transmit a blue light having a central wavelength in, e.g., a range of 420 nm to 480 nm.

Each of the color filters CFR, CFG, and CFB may include a photosensitive resin and a colorant including a pigment and/or dye. The first color filter CFR may include a red pigment and/or a red dye, the second color filter CFG may include a green pigment and/or a green dye, and the third color filter CFB may include a blue pigment and/or a blue dye.

The color filters CFR, CFG and CFB may be defined or partitioned by the light-shielding portion BM. A plurality of the light-shielding portion BM may be spaced apart from each other with the color filters CFR, CFG and CFB interposed therebetween. A plurality of the color filters CF may be arranged between the light-shielding portions BM.

For example, the light-shielding portion BM may be disposed between the first light-emitting device ED1 and the second light-emitting device ED2, between the second light-emitting device ED2 and the third light-emitting device ED3, and between the first light-emitting device ED1 and the third light-emitting device ED3.

In example embodiments, one end portion of the first color filter CFR may be disposed on the light-shielding portion BM, and one end portion of the third color filter CFB may be disposed on the first color filter CFR disposed on the light-shielding portion BM. Accordingly, reflectance may be reduced in a boundary region between the pixels PX-R, PX-G and PX-B, and diffraction by the external light may be reduced.

For example, the first color filter CFR and the third color filter CFB which may be sequentially stacked on the light-shielding portion BM may form a double bridge structure, so that reflectance may be decreased in the boundary region between the pixels PX-R, PX-G and PX-B.

In some embodiments, as illustrated in FIG. 5, the one end portion of the first color filter CFR and the one end portion of the third color filter CFB may be sequentially disposed on the light-shielding portion BM adjacent to the second color filter CFG. In this case, the second color filter CFG may cover the one end portion of the third color filter CFB in the thickness direction. Accordingly, reflectance in the boundary region between the pixels PX-R, PX-G and PX-B may be further reduced.

Referring to FIG. 6, a first spacing distance D1 between the one end portion of the first color filter CFR and the one end portion of the third color filter CFB in a plan view may be in a range from 0.1 μm to 5.0 μm. In some embodiments, the first spacing distance D1 may be in a range from 0.5 μm to 3.5 μm. In the above range, reflectance (SCI, SCE) may be reduced while maintaining or improving a side viewing angle luminance ratio (LvA) of the display device and/or the color filter layer.

In some embodiments, a second spacing distance D2 between one end portion of the light-shielding portion BM and the one end portion of the first color filter CFR in a plan view may be in a range from 0.1 μm to 5.0 μm. In an embodiment, the second spacing distance D2 may be in a range from 0.5 μm to 3.5 μm. In the above range, reflectance in the boundary region of the pixels PX-R, PX-G and PX-B may be reduced, and color reproducibility may be improved.

In some embodiments, the color filter layer CFL may include second openings OPR2, OPG2 and OPB2 exposing the first color filter CFR, the second color filter CFG and the third color filter CFB. For example, the second openings OPR2, OPG2 and OPB2 may be defined by a sidewall of the light-shielding portion BM.

For example, the first light-emitting device ED1 may be exposed by the second-first opening OPR2 through the first color filter CFR, the second light-emitting device ED2 may be exposed by the second-second opening OPG2 through the second color filter CFG, and the third light-emitting device ED3 may be exposed by the second-third opening OPB3 through the third color filter CFB. The “exposure” may indicate an exposure of a top surface or an upper surface.

In some embodiments, the second openings OPR2, OPG2 and OPB2 may have a circular shape or an elliptical shape in a plan view. Accordingly, diffraction and/or reflection due to the external light may be further suppressed.

In some embodiments, each diameter of the second openings OPR2, OPG2 and OPB2 may be greater than each diameter of the first openings OPR1, OPG1 and OPB1 in a plan view. Accordingly, light efficiency and color reproducibility of the display device may be further improved.

In example embodiments, a protective layer PL may be further disposed under a bottom surface of the color filter layer CFL. For example, the protective layer PL may include a multi-layered structure. Accordingly, penetration of moisture and/or impurities from an outside the display device into the lower structure LS in which the light emitting-devices ED1, ED2 and ED3 are included may be further suppressed.

For example, as illustrated in FIG. 5, the protective layer PL may include a first protective layer PL1 disposed on the encapsulation layer TFE and a second protective layer PL2 disposed on the first protective layer PL1. In some embodiments, the encapsulation layer TFE may be disposed between the light-emitting portion and the protective layer PL.

For example, the protective layer PL may include substantially the same type of material as that of the encapsulation layer TFE. For example, the protective layer PL may include silicon nitride (SiNx), silicon oxide (SiOx), indium tin oxide, indium zinc oxide, or the like.

In example embodiments, an overcoat layer OC may be disposed on the color filter layer CFL.

For example, the overcoat layer OC may serve as a planarization layer covering upper surfaces of the color filters CFR, CFG and CFB, and the light-shielding portion BM. Accordingly, the upper substrate 200 may be stacked on the overcoat layer OC and stably disposed on the color filter layer CFL.

The upper structure US including the upper substrate 200, the color filter layer CFL, the protective layer PL and the overcoat layer OC as described above may be laminated or combined with the lower structure LS using a sealant 90 or the encapsulation layer TFE.

FIGS. 7A and 7B are schematic cross-sectional views illustrating light-emitting devices in accordance with example embodiments.

Referring to FIGS. 7A and 7B, the light-emitting device ED may include the light-emitting portion EL disposed between the pixel electrode 180 and the counter electrode 190.

As illustrated in FIG. 7A, the light-emitting portion EL may include a hole transport layer HTL, an emission layer EML and an electron transport layer ETL. In example embodiments, the hole transport layer HTL, the emission layer EML, the electron transport layer ETL and the counter electrode 190 may be sequentially stacked from a top surface of the pixel electrode 180.

In some embodiments, the light-emitting portion EL may include an emission layer EML including an organic light-emitting material capable of emitting a blue light having a central wavelength in, e.g., a range of 420 nm to 480 nm.

As illustrated in FIG. 7B, the light-emitting portion EL may include a plurality of light-emitting structures ES1, ES2 and ES3. Each of the light emitting structures ES1, ES2 and ES3 may include a hole transport layer, an emission layer and an electron transport layer. In example embodiments, the light-emitting device ED of FIG. 7B may be a light emitting-device having a tandem structure.

Charge generation layers CGL1 and CGL2 may be disposed between neighboring light emitting structures ES1, ES2 and ES3. The charge generation layers CGL1 and CGL2 may include a p-type charge generation layer and/or an n-type charge generation layer. The charge generation layers CGL1 and CGL2 may include a first charge generation layer CGL1 between the first light-emitting structure ES1 and the second light-emitting structure ES2, and a second charge generation layer CGL2 between the second light-emitting structure ES2 and the third light-emitting structure ES3.

In example embodiments, the first light-emitting structure ES1, the first charge generation layer CGL1, the second light-emitting structure ES2, the second charge generation layer CGL2, the third light-emitting structure ES3, and the counter electrode 190 may be sequentially stacked from the top surface of the pixel electrode 180.

In some embodiments, as illustrated in FIG. 5, the light-emitting portion EL may be individually patterned within the light-emitting region defined by the pixel defining layer PDL. Accordingly, the light-emitting portions EL may be separated from each other in the form of an island where the light-emitting portions EL are spaced apart from each other in a plurality of the pixels.

In some embodiments, the light emitting-portion EL may extend continuously and commonly throughout a plurality of the pixels and top surfaces of the pixel defining layer PDL.

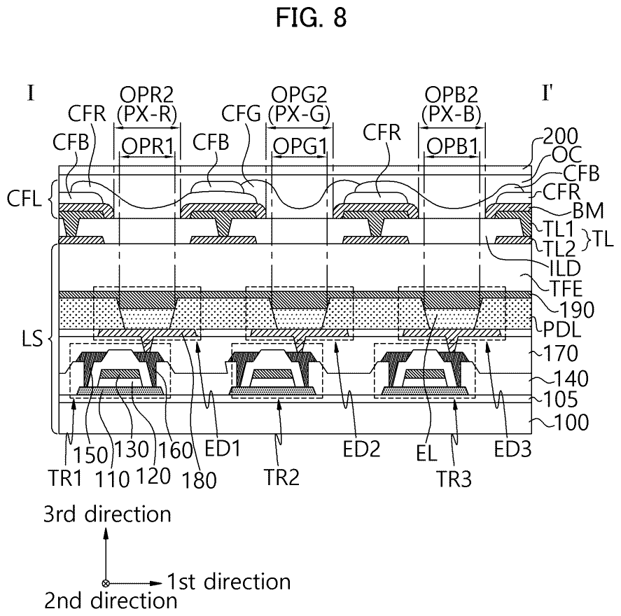

FIG. 8 is a schematic cross-sectional view illustrating a display device or a display panel according to some embodiments. Detailed descriptions on elements and structures substantially the same as or similar to those described with reference to FIG. 5 are omitted herein.

Referring to FIG. 8, a touch sensor layer TL may be added on the encapsulation layer TFE. In some embodiments, the touch sensor layer may include sensor electrode layers TL1 and TL2 formed in an on-cell type.

In some embodiments, the second sensor electrode layer TL2 and the first sensor electrode layer TL1 may be disposed on the encapsulation layer TFE. The second sensor electrode layer TL2 and the first sensor electrode layer TL1 may be disposed at different levels with a sensor insulating interlayer ILD interposed therebetween.

In some embodiments, a touch buffer layer may be disposed on the encapsulation layer TFE, and the second sensor electrode layer TL2, the sensor insulating interlayer ILD and the first sensor electrode layer TL1 may be sequentially disposed on the touch buffer layer. The touch buffer layer may be provided as a base layer of the second sensor electrode layer TL2, and may be formed directly on the encapsulation layer TFE.

The sensor insulating interlayer ILD may be provided as a base layer of the first sensor electrode layer TL1, and may be formed on the second sensor electrode layer TL2.

In some embodiments, the first sensor electrode layer TL1 may include a plurality of touch sensing electrode patterns. The second sensor electrode layer TL2 may include connection electrodes or bridge electrodes electrically connecting some of the touch sensing electrode patterns to each other.

In some embodiments, the first sensor electrode layer TL1 may include the connection electrode or the bridge electrodes, and the second sensor electrode layer TL2 may include the sensing electrode patterns.

The touch buffer layer and the sensor insulating interlayer ILD may include an inorganic insulating material such as silicon oxide, silicon nitride, and/or silicon oxynitride, or an organic insulating material. The sensor electrode layers TL1 and TL2 may include a transparent conductive oxide such as a metal/alloy or ITO. In an embodiment, the sensing electrode patterns may have a mesh structure and may have improved light transmittance.

In some embodiments, the first sensor electrode layer TL1 and the second sensor electrode layer TL2 may overlap the pixel defining layer PDL so as not to overlap the pixels PX-R, PX-G and PX-B.

The light-shielding portion BM may cover the first sensor electrode layer TL1 on the sensor insulating interlayer ILD. For example, the light-shielding portion BM may cover the touch sensing electrode patterns included in the first sensor electrode layer TL1. Thus, light reflection and light path disturbance caused by the touch sensing electrode patterns may be prevented.

In example embodiments, the color filter layer CFL may be disposed on the touch sensing electrode patterns based on the construction as described with reference to FIGS. 5 and 6.

In some embodiments, the light-shielding portion BM may be omitted. In this case, the first sensor electrode layer TL1 and/or the second sensor electrode layer TL2 may be substantially provided as the light-shielding portion. In an embodiment, the color filter layer CFL may be disposed directly on the touch sensing electrode patterns included in the first sensor electrode layer TL1.

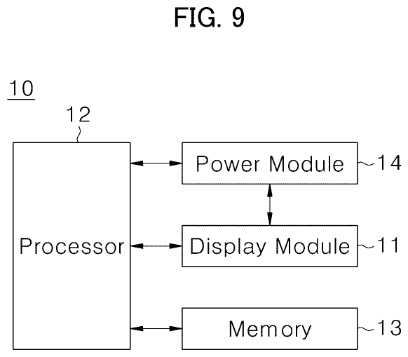

FIG. 9 is a block diagram of an electronic device 10 in accordance with an embodiment.

Referring to FIG. 9, the electronic device 10 according to an embodiment may include a display module 11, a processor 12, a memory 13 and a power module 14.

The processor 12 may include a central processing unit (CPU), an application processor (AP), a graphic processing unit (GPU), a communication processor (CP), an image signal processor (ISP) and/or a controller.

Data information for an operation of the processor 12 or the display module 11 may be stored in the memory 13. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts a power supplied by the power supply module to a generate power required for the operation of the electronic device 10.

At least one of components of the electronic device 10 as described above may be included in the display device according to the above-described embodiments. Additionally, some of individual modules functionally included in one module may be included in the display device, and others may be provided separately from the display device. For example, the display module 11 may include the display device, and the processor 12, the memory 13 and the power module 14 may be provided in the form of another device in the electronic device 10 different from the display device.

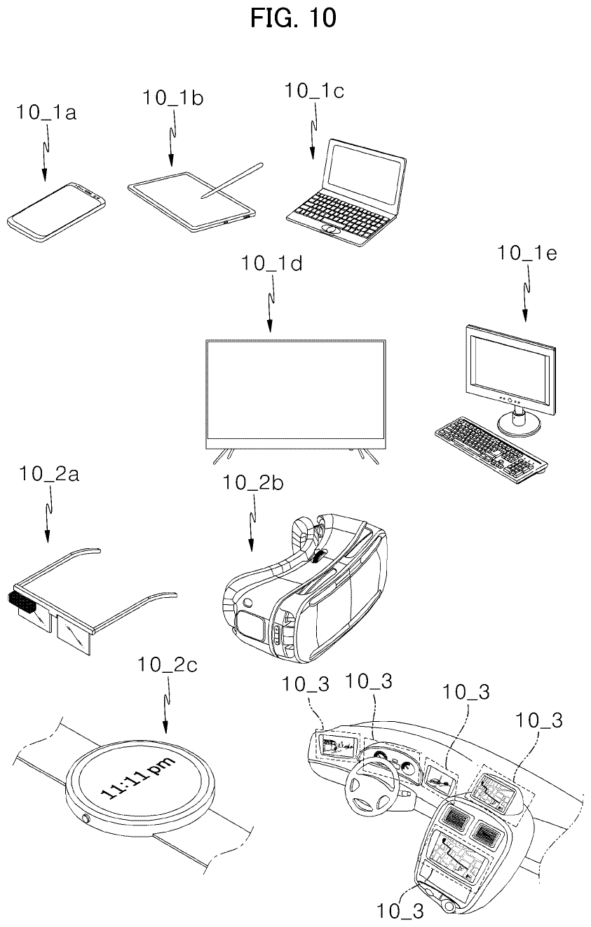

FIG. 10 is a schematic diagram of an electronic device in accordance with various embodiments.

Referring to FIG. 10, non-limiting examples of various electronic devices to which the display device according to the above-described embodiments is applied include an electronic device for displaying an image such as a smartphone 10_1a, a tablet PC 10_1b, a laptop 10_1c, a TV 10_1d, a desk monitor 10_1e, and the like; a wearable electronic device including a display module such as smart glasses 10_2a, a head mounted display 10_2b, a smart watch 10_2c, and the like; a vehicle electronic device 10_3 including a display module such as a center information display (CID) disposed at a vehicle instrument panel, a center fascia, a dashboard, etc., a room mirror display, and the like. The electronic device may include a virtual reality glass or an augmented reality glass.

Hereinafter, embodiments of the present disclosure are described in more detail with reference to experimental examples. However, the following examples are only given for illustrating the inventive concept and those skilled in the related art will obviously understand that various alterations and modifications are possible within the scope and spirit of the inventive concept. Such alterations and modifications are duly included in the appended claims.

### Experimental Example

### (1) An Example

A display device having the arrangement and shape illustrated in FIGS. 1 to 5 and 7A was manufactured. Each of the first spacing distance D1 and the second spacing distance D2 was adjusted as shown in Table 1.

### (2) A Comparative Example

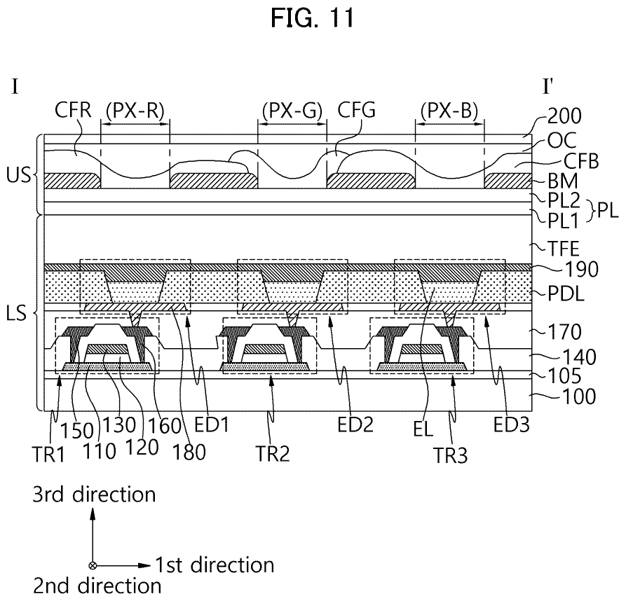

FIG. 11 is a cross-sectional view of a display device of the Comparative Example taken along a line I-I′ of FIG. 4 in a thickness direction.

A display device having the arrangement and shape illustrated in FIGS. 1 to 4, 7A and 11 was manufactured. Referring to FIG. 11, the display device of the Comparative Example was manufactured such that the first color filter CFR and the third color filter CFB were not stacked in a double-layered structure on the light-shielding portion BM.

### (3) Measurement of Reflectance

SCI (Specular Component Included) and SCE (Specular Component Excluded) of the above-described Example and the Comparative Example were measured, and the results are shown in Table 1 below.

TABLE 1

| | D1(μm) | D2(μm) | SCI | SCE |
|---|---|---|---|---|
| Example | 2.0 | 2.0 | 5.70 | 0.48 |
| Comparative Example | — | — | 5.92 | 0.55 |

Referring to Table 1, in the Example where one end portion of the first color filter and one end portion of the third color filter were sequentially stacked on the light-shielding portion and the first spacing distance D1 was adjusted in a range of 0.1 μm to 5.0 μm, and the reflectance (SCI and SCE) was reduced compared to that from the Comparative Example, thereby improving image quality.

Additionally, when the first spacing distance D1 was reduced to less than 0.1 m, the effect of the double-layered structure of the first color filter CFR and the third color filter CFB on the light-shielding portion BM was not substantially implemented. Accordingly, the reflectance similar to that from the Comparative Example was obtained. When the first spacing distance D1 was increased to exceed 5.0 μm, the reflectance was increased due to an increase in a stepper length between the color filters, and SCI and SCE values were increased compared to those from the Example.

What is claimed is:

1. A display device, comprising:
a light-emitting region including a first light-emitting device, a second light-emitting device, and a third light-emitting device that are spaced apart from each other; and
a color filter layer including a light-shielding portion, a first color filter that overlaps the first light-emitting device in a thickness direction, a second color filter that overlaps the second light-emitting device in the thickness direction, and a third color filter that overlaps the third light-emitting device in the thickness direction,
wherein one end portion of the first color filter is disposed on the light-shielding portion, and one end portion of the third color filter is disposed on the first color filter on the light-shielding portion, and
a first spacing distance between the one end portion of the first color filter and the one end portion of the third color filter in a plan view is in a range from 0.1 μm to 5.0 μm.

2. The display device of claim 1, wherein the first spacing distance is in a range from 0.5 μm to 3.5 μm.

3. The display device of claim 1, wherein the light-shielding portion is disposed between the first light-emitting device and the second light-emitting device, between the second light-emitting device and the third light-emitting device, and between the first light-emitting device and the third light-emitting device in the plan view.

4. The display device of claim 1, wherein the one end portion of the first color filter and the one end portion of the third color filter are sequentially arranged on the light-shielding portion adjacent to the second color filter.

5. The display device of claim 4, wherein the second color filter covers the one end portion of the third color filter in the thickness direction.

6. The display device of claim 1, wherein the light-emitting region further includes a pixel defining layer that includes a first opening exposing the first light-emitting device, the second light-emitting device or the third light-emitting device.

7. The display device of claim 6, wherein the first opening has a circular shape or an elliptical shape.

8. The display device of claim 6, wherein the first opening is defined by a side wall of the pixel defining layer.

9. The display device of claim 6, wherein the color filter layer includes a second opening that exposes the first color filter, the second color filter or the third color filter.

10. The display device of claim 9, wherein the second opening has a circular shape or an elliptical shape.

11. The display device of claim 9, wherein the second opening is defined by a side wall of the light-shielding portion.

12. The display device of claim 1, wherein the light-emitting region further includes a pixel defining layer including a first opening that exposes the first light-emitting device, the second light-emitting device or the third light-emitting device,
the color filter layer includes a second opening exposing the first color filter, the second color filter or the third color filter, and
a diameter of the second opening is larger than a diameter of the first opening in the plan view.

13. The display device of claim 1, wherein a second spacing distance between one end portion of the light-shielding portion and the one end portion of the first color filter in the plan view is in a range from 0.1 μm to 5.0 μm.

14. The display device of 13, wherein the second spacing distance is in a range from 0.5 μm to 3.5 μm.

15. The display device of claim 1, wherein the first light-emitting device, the second light-emitting device and the third light-emitting device are a red light-emitting device, a green light-emitting device and a blue light-emitting device, respectively, and
the first color filter, the second color filter and the third color filter are a red color filter, a green color filter and a blue color filter, respectively.

16. A display device, comprising:
a substrate;
a first light-emitting device, a second light-emitting device and a third light-emitting device spaced apart from each other on the substrate;
an encapsulation layer covering the first light-emitting device, the second light-emitting device and the third light-emitting device on the substrate;
a touch sensor layer disposed on the encapsulation layer, the touch sensor layer including a touch sensing electrode pattern; and
a color filter layer on the touch sensor layer, the color filer layer including a first color filter that overlaps the first light-emitting device in a thickness direction, a second color filter that overlaps the second light-emitting device in the thickness direction, and a third color filter that overlaps the third light-emitting device in the thickness direction,
wherein one end portion of the first color filter is disposed on the touch sensing electrode pattern, one end portion of the third color filter is disposed on the first color filter on the touch sensing electrode pattern, and
a first spacing distance between the one end portion of the first color filter and the one end portion of the third color filter in a plan view is in a range from 0.1 μm to 5.0 μm.

17. The display device of claim 16, further comprising a light-shielding portion covering the touch sensing electrode pattern.

18. The display device of claim 16, wherein the touch sensor layer includes a second sensor electrode layer, a sensor insulating interlayer, and a first sensor electrode layer sequentially staked on the encapsulation layer.

19. The display device of claim 16, wherein a second spacing distance between one end portion of the touch sensing electrode pattern and the one end portion of the first color filter in the plan view is in a 0.1 μm to 5.0 μm.

20. An electronic device, comprising:
a display device;
a memory; and
a processor for executing data included in the memory to control an operation of the display device,
wherein the display device comprises:
a light-emitting region including a first light-emitting device, a second light-emitting device and a third light-emitting device that are spaced apart from each other; and
a color filter layer including a light-shielding portion, a first color filter that overlaps the first light-emitting device in a thickness direction, a second color filter that overlaps the second light-emitting device in the thickness direction, and a third color filter that overlaps the third light-emitting device in the thickness direction,
wherein one end portion of the first color filter is disposed on the light-shielding portion, and one end portion of the third color filter is disposed on the first color filter on the light-shielding portion, and
a first spacing distance between the one end portion of the first color filter and the one end portion of the third color filter in a plan view is in a range from 0.1 μm to 5.0 μm.
